(19) United States
(12) Patent Application Publication
(10) Pub. No.: US 2010/0187606 A1
(43) Pub. Date: Jul. 29, 2010

(54) SEMICONDUCTOR DEVICE THAT INCLUDES LDMOS TRANSISTOR AND MANUFACTURING METHOD THEREOF

(76) Inventors: Yasushi KOBAYASHI, Osaka (JP); Masaki Inoue, Osaka (JP); Kohei Miyagawa, Osaka (JP)

Correspondence Address: MCDERMOTT WILL & EMERY LLP, 600 13TH STREET, NW, WASHINGTON, DC, 20005-3096, US

(21) Appl. No.: 12/690,766

(22) Filed: Jan. 20, 2010

(30) Foreign Application Priority Data
Jan. 27, 2009 (JP) 2009-015909

(51) Int. Cl. H01L 29/78; H01L 21/336; H01L 21/8238

(52) U.S. Cl. 257/338; 438/286; 438/225; 257/E21.417; 257/E21.642; 257/E29.256

(57) ABSTRACT

A manufacturing method of a semiconductor device including an LDMOS transistor includes: a process (a) of forming a first conductive well diffusion layer in the semiconductor substrate; a process (b) of sequentially forming a gate insulator film, a gate conductive film, and a photoresist film on a region on the semiconductor substrate corresponding to the well diffusion layer; a process (c) of performing photolithography to remove a part of the photoresist film formed in a predetermined region, and etching the gate conductive film using a remaining part of the photoresist film as a mask so as to form an opening in the predetermined region; a process (d) of doping second conductive impurity ions using a remaining part of the gate conductive film and the remaining part of the photoresist film as a mask so as to form the body layer; and a process (e) of removing the remaining part of the gate conductive film except a part corresponding to the gate electrode formed based on a part that constitutes a lateral surface of the gate conductive film facing the opening.

This disclosure of Japanese Patent Application No. 2009-015909 filed Jan. 27, 2009 including specification, drawings and claims is incorporated herein by reference in its eternity.

### BACKGROUND OF THE INVENTION

(1) Field of the Invention

The present invention relates to a manufacturing method of a semiconductor device that includes an LDMOS transistor.

(2) Related Art

With recent high integration of semiconductor integrated circuit devices, there arises a demand for semiconductor integrated circuit devices including a high voltage LDMOS (Laterally Diffused Metal Oxide Semiconductor) element, a low voltage CMOS (Complementary Metal Oxide Semiconductor) element, a bipolar element, and the like that are integrated in the same substrate. An LDMOS transistor that is an example of the high voltage LDMOS element is demanded to have less power consumption and size for mobile apparatuses. Furthermore, such an LDMOS transistor is demanded to include other element having a low voltage in the same substrate, and realize characteristics such as a low threshold voltage, a high voltage, and a low on-resistance.

Here, Japanese Patent Application Publication No. 2001-060686 (hereinafter, “Patent Literature”) discloses an art relating to the size reduction of LDMOS transistors. Also, Literature [International Symposium on Power Semiconductor Devices & IC's 2008 “BD180-A New 0.18 μm BCD (Bipolar-CMOS-DMOS) Technology from 7 V to 60 V”] (hereinafter, “Non-Patent Literature”) discloses an example of a manufacturing method of an LDMOS transistor and the structure thereof.

The LDMOS transistor disclosed in the above Non-Patent Literature is manufactured by forming a high concentration p-type body layer in an n-well layer, forming an n-type source diffusion layer and an n- type drain diffusion layer respectively in a p-type body layer and the n-well layer, and forming a gate insulator film and a gate electrode so as to partially overlap the p-type body layer (see FIG. 1 of the Non-Patent Literature). Also, the p-type body layer has a sufficiently higher impurity concentration than that of the n-well layer, and is sufficiently narrower than that of the n-well region. In this way, by providing a high concentration p-type body layer and a low concentration n-well region, it is possible to form a short channel in the p-type body layer at a low threshold voltage and realize a high voltage and a low on-resistance.

Here, it is known that shortening of the channel length and reduction in threshold voltage are effective for reduction in power consumption of LDMOS transistors. However, the capability of the LDMOS transistor having a shorter channel length is more influenced by slight variation in channel length.

Therefore, it is necessary to form a p-type body layer and a gate electrode that determine the channel length in precise positions.

However, according to the manufacturing method disclosed in the Non-Patent Literature, a gate electrode is formed after a p-type body layer is formed. This causes variation in relative position between the gate electrode and the p-type body layer for each transistor due to mask rubbing or the like.

In response to such a problem, there has been proposed a self-alignment technique using a gate electrode as a mask (see FIG. 3 of the Patent Literature). According to the self-alignment technique, a region other than a region in which a body layer is intended to be formed is masked using a photoresist film, and p-type impurities are doped. Here, it is known that a photoresist film is formed on the gate electrode to the extent where the photoresist film does not cover an end surface of the gate electrode that functions as a mask for doping impurities.

### SUMMARY OF THE INVENTION

However, even with use of the self-alignment technique disclosed in the above Patent Literature, there is variation in position between the end surface of the gate electrode and the photoresist film on the gate electrode. This causes a problem that it is not the necessarily the case that a p-type body layer can be formed within an intended range. Specifically, there is a case that impurity ions pass through a region of the gate electrode that is not covered by the photpresist film and reach the substrate. If such a case causes variation in relative positional relationship between an end surface of a gate electrode and a photoresist film formed on the gate electrode, there occurs variation in range and area in which the p-type body layer and the gate electrode overlap each other. This results in variation in channel length for each manufactured transistor, and it is impossible to stably manufacture transistors having low threshold voltage.

Also, in order to diffuse a p-type body layer formed using the self -alignment technique in the lateral direction, it is necessary to perform high heat treatment processing at a temperature of 1000° C. or higher. In the case where other element such as a CMOS is formed in the same substrate in which the p-type body layer is formed, there occurs a problem that other element is influenced by the high heat treatment processing.

Although these problems have been described above with respect to n-channel LDMOS transistors, similar problems also occur in p-channel LDMOS transistors.

The present invention is made in view of the above problem, and aims to provide a semiconductor device that includes an LDMOS transistor having a small variation in channel length and a stable manufacturing method of the semiconductor device.

In view of the above problem, the present invention provides a manufacturing method of a semiconductor device including a first conductive LDMOS transistor that is composed of a first conductive drain diffusion layer and a second conductive body layer formed in a semiconductor substrate, a first conductive source diffusion layer and a body contact layer formed in the body layer, and a gate electrode formed on a region between the drain diffusion layer and the source diffusion layer, the manufacturing method comprising: a process (a) of forming a first conductive well diffusion layer in the semiconductor substrate; a process (b) of sequentially forming a gate insulator film, a gate conductive film, and a photoresist film on a region on the semiconductor substrate corresponding to the well diffusion layer; a process (c) of performing photolithography to remove a part of the photoresist film formed in a predetermined region, and etching the gate conductive film using a remaining part of the photoresist film as a mask so as to form an opening in the predetermined region; a process (d) of doping second conductive impurity ions using a remaining part of the gate conductive film and the remaining part of the photoresist film as a mask so as to form the body layer; and a process (e) of removing the remaining part of the gate conductive film except a part corresponding to the gate electrode formed based on a part that constitutes a lateral surface of the gate conductive film facing the opening.

According to the manufacturing method of the semiconductor device relating to the present invention, a gate conductive film is etched using a photoresist film as a mask so as to form an opening. As a result, since the gate conductive film completely conforms to the photoresist, there is no impurity ions that pass through the gate conductive film and reach the semiconductor substrate. A position where a body layer is to be formed and an area thereof are determined depending on a position and an area of the opening.

Furthermore, in the process (d), the gate electrode is formed based on a part of a lateral surface of the gate conductive film facing the opening. This can suppress variation in positional relationship between a gate electrode and a body layer for each transistor. In other words, the manufacturing method of the semiconductor device relating to the present invention can suppress variation in channel length for each transistor. As a result, it is possible to exhibit an excellent effect that variation in threshold voltage for each transistor can be also suppressed.

Also, in the manufacturing method of the semiconductor device relating to the present invention, in the process (d), the second conductive impurity ions may be doped while an incidence angle thereof is changed within a predetermined range. According to this manufacturing method, the incidence angle of the impurity ions for forming the body layer is inclined within the predetermined range in the normal line direction of the semiconductor substrate. As a result, since the impurity ions are diffused not only directly below the opening but also are diffused around the opening, it is unnecessary to perform high heat treatment processing for diffusing the body layer in the lateral direction. Accordingly, even in the case where other element is formed in the same substrate, the element is not influenced by the high heat treatment processing.

Also, in the process (d), the impurity ions may be doped such that the LDMOS transistor has a channel length within a range from 0.1 μm to 0.4 μm. With this structure, it is possible to suppress the threshold voltage of the LDMOS transistor to 1 [V] or less.

The manufacturing method of the semiconductor device relating to the present invention may further comprise a process of forming an insulator film in a position between the drain diffusion layer and the gate electrode. Semiconductor devices manufactured by this manufacturing method each includes an insulator film between a gate electrode and a drain diffusion layer. By including an insulator film in this way, it is possible to suppress the concentration of electrical field around a position where a distance between the gate electrode and the drain diffusion layer is small, and improve the voltage resistance between gate and drain and the voltage resistance between source and drain.

The semiconductor device relating to the present invention comprises at least one LDMOS transistor, and is manufactured by the above manufacturing method relating to the present invention.

Also, the present invention provides a manufacturing method of a semiconductor device including a complementary MOS transistor and a complementary LDMOS transistor that are formed in a same semiconductor substrate, the manufacturing method comprising: a process (a) of, in a semiconductor substrate in which a plurality of isolation insulator films are formed, forming a first well diffusion layer having a first conductivity type in a first region defined by one of the isolation insulator films, and forming a second well diffusion layer having the first conductivity type in a second region that is different from the first region; a process (b) of forming a third well diffusion layer having a second conductivity type and a fourth well diffusion layer having the second conductivity type respectively in a third region and a fourth region in the semiconductor substrate that are each different from the first and second regions; a process (c) of sequentially forming a gate insulator film, a gate conductive film, and a photoresist film on a part on the semiconductor substrate corresponding to the first to fourth regions; a process (d) of performing photolithography to remove a part of the photoresist film that is formed in a predetermined range of the first region, and etching the gate conductive film using a remaining part of the photoresist film as a mask so as to form a first opening; a process (e) of doping second conductive impurity ions using a remaining part of the gate conductive film and the remaining part of the photoresist film so as to form a first body layer; a process (f) of removing the remaining part of the photoresist film, and forming a new photoresist film on the part corresponding to the first to fourth regions; a process (g) of performing photolithography to remove a part of the new photoresist film that is formed in a predetermined range of the second region, and etching the remaining part of the gate conductive film using a remaining part of the new photoresist film as a mask so as to form a second opening; a process (h) of doping first conductive impurity ions using a part of the gate conductive film remaining after being etched and the remaining part of the new photoresist film as a mask so as to form a second body layer having the first conductivity type; a process (i) of removing the gate conductive film except a part of the first region corresponding to the gate electrode formed based on a part that constitutes a lateral surface of the gate conductive film facing the first opening, a part of the third region corresponding to the gate electrode formed based on a part that constitutes a lateral surface of the gate conductive film facing the second opening, and parts of the second and fourths regions corresponding to the gate electrode; a process (j) of forming a first-conductive drain diffusion layer in the first well diffusion layer, forming a first-conductive source diffusion layer in the first body layer, forming a first-conductive body contact layer in the second well diffusion layer, forming a first-conductive body contact layer in the third body layer, and forming a first-conductive source diffusion layer and a first-conductive drain diffusion layer in the fourth well diffusion layer; and a process (k) of forming a second-conductive body contact layer on the first body layer, forming a second-conductive source diffusion layer and a second-conductive drain diffusion layer in the second well diffusion layer, forming a second-conductive drain diffusion layer on the third well diffusion layer, forming a second-conductive source diffusion layer in the third body layer, and forming a second-conductive body contact layer in the fourth well diffusion layer.

According to the manufacturing method of the semiconductor device relating to the present invention, it is possible to simultaneously form the first conductive LDMOS transistor in the first region, the second conductive MOS transistor in the second region, the second conductive LDMOS transistor in the third region, and the first conductive MOS transistor in the fourth region. Here, in the process (i), remaining parts of the gate conductive film that have not been removed correspond to a gate electrode in each of the transistors.

According to the manufacturing method of the semiconductor device relating to the above present invention, the gate conductive film is etched using the photoresist film as a mask so as to form the first and second openings. As a result, since the gate conductive film completely conforms to the photoresist, there is no impurity ions that pass through the gate conductive film and reach the semiconductor substrate, and positions where the first and second body layers are intended to be formed and areas thereof are determined depending on positions where the first and second openings are formed and areas thereof.

Furthermore, according to the manufacturing method of the semiconductor device relating to the above present invention, the gate electrode of the LDMOS transistor is formed based on the parts of the lateral surfaces of the gate conductive film facing the first and second openings. This can suppress the variation in positional relationship between the gate electrode and the body layer of the LDMOS transistor, that is, the variation in channel length for each transistor.

Also, in the process (c), the gate insulator films may be formed in the first and third regions so as to have film thicknesses thicker than film thicknesses of the gate insulator films formed in the second and fourth regions. In this case, the semiconductor device relating to the present invention is manufactured by this manufacturing method, and is characterized that the complementary LDMOS transistor has the gate insulator film having a film thickness different from a film thickness of the gate insulator film of the complementary MOS transistor.

According to the manufacturing method of the semiconductor device relating to the above present invention, it is possible to vary the film thickness of the gate insulator film between the LDMOS transistor and the MOS transistor. The voltage that can be applied to the transistor varies depending on the film thickness of the gate insulator film. Accordingly, it is possible to freely change the voltage characteristics for each transistor depending on the intended use and purpose, by adjusting the film thickness of the gate insulator film.

Also, in the manufacturing method of the semiconductor device relating to the above present invention, the semiconductor device may comprise: a first-conductive LDMOS transistor formed in the first region; a second-conductive MOS transistor formed in the second region; a second-conductive LDMOS transistor formed in the third region; and a first-conductive MOS transistor formed in the fourth region, and in the process (c), the gate insulator is formed in a range of the first and third regions in which the gate electrode and the body layer having the first or second conductivity are to be formed so as to have a film thickness thinner than a film thickness of the gate insulator formed in other region.

In the case where, as described above, the gate insulator is formed in a range of the first and third regions in which the gate electrode and the body layer having the first or second conductivity are to be formed so as to have a film thickness thinner than a film thickness of the gate insulator formed in other region, the gate insulator film to be etched has the substantially uniform film thickness in the process (i). This can suppress the excessive etching of the semiconductor substrate and the reduction in film thickness of the isolation insulator film.

### BRIEF DESCRIPTION OF THE DRAWINGS

These and other objects, advantages and features of the invention will become apparent from the following description thereof taken in conjunction with the accompanying drawings which illustrate a specific embodiment of the invention. In the drawing:

FIG. 1 is a sectional view showing a semiconductor device under a process (a) of a manufacturing method relating to a first embodiment;

FIG. 2 is a sectional view showing the semiconductor device under a process (b) of the manufacturing method relating to the first embodiment;

FIG. 3 is a sectional view showing the semiconductor device under a under a process (c) of the manufacturing method relating to the first embodiment;

FIG. 4 is a sectional view showing the semiconductor device under a process (d) of the manufacturing method relating to the first embodiment;

FIG. 5 is a sectional view showing the semiconductor device under a process (e) of the manufacturing method relating to the first embodiment;

FIG. 6 is a sectional view showing the semiconductor device under a process (f) of the manufacturing method relating to the first embodiment;

FIG. 7 is a sectional view showing the semiconductor device under processes (g) and (h) of the manufacturing method relating to the first embodiment;

FIG. 8 is a sectional view showing the semiconductor device under a process (i) of the manufacturing method relating to the first embodiment;

FIG. 9 is a sectional view showing the semiconductor device under a process (j) of the manufacturing method relating to the first embodiment;

FIG. 10 is a sectional view showing the semiconductor device under a process (k) of the manufacturing method relating to the first embodiment;

FIG. 11 is a sectional view showing a semiconductor device relating to a second embodiment;

FIG. 12 is a sectional view showing a semiconductor device relating to a third embodiment;

FIG. 13 is a sectional view showing a semiconductor device under a process (c4) of a manufacturing method relating to a fourth embodiment;

FIG. 14 is a sectional view showing the semiconductor device under a process (d4) of the manufacturing method relating to the fourth embodiment;

FIG. 15 is a sectional view showing the semiconductor device under a process (e4) of the manufacturing method relating to the fourth embodiment;

FIG. 16 is a sectional view showing the semiconductor device under a process (m4) of the manufacturing method relating to the fourth embodiment;

FIG. 17 is a sectional view showing a semiconductor device on which process of a manufacturing method relating to a modification example of the fourth embodiment have not been performed yet;

FIG. 18 is a sectional view showing the semiconductor device under a process (d4′) of the manufacturing method relating to the modification example of the fourth embodiment;

FIG. 19 is a sectional view showing a semiconductor device on which a process (k4) of the modification example of the fourth embodiment has been performed; and

FIG. 20 is the sectional view showing a semiconductor device manufactured by the manufacturing method relating to the modification example of the fourth embodiment.

### DESCRIPTION OF PREFERRED EMBODIMENTS

The following describes preferred embodiments for implementing the present invention with use of some examples.

The embodiments used in the following description are examples for easily explaining the structures and effects of the present invention. The present invention is not limited by the following embodiments except essential points thereof.

### First Embodiment

The following describes a manufacturing method of a semiconductor device as an example of an embodiment of the present invention.

1. Outline

In a first embodiment, the following describes a manufacturing method of a semiconductor device including a complementary LDMOS transistor and a CMOS transistor that are provided in the same semiconductor substrate.

Both the complementary LDMOS transistor and the CMOS transistor are each a field-effect transistor. However, for convenience of description, two transistors constituting the complementary LDMOS transistor are referred to as a “p-channel LDMOS transistor” and an “n-channel LDMOS transistor”, and two field-effect transistors having a general structure constituting the CMOS transistor are referred to as a “p-channel MOS transistor” and an “n-channel MOS transistor”.

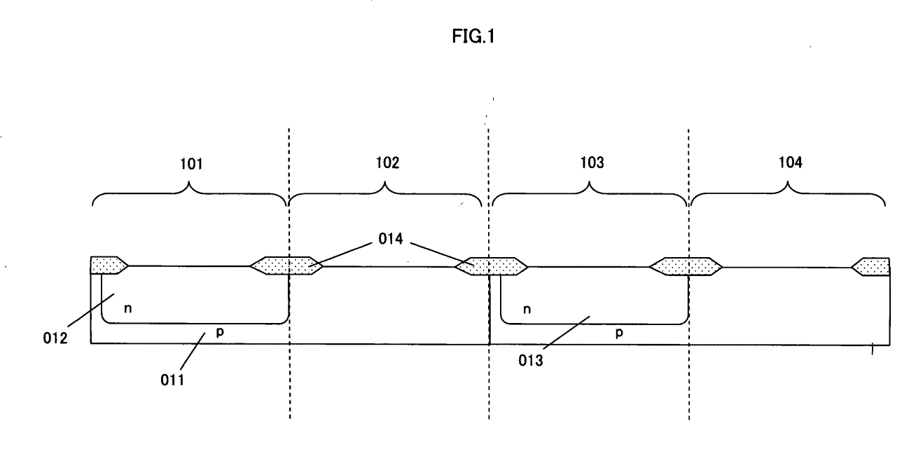

FIG. 1 to FIG. 10 are sectional views each showing a semiconductor device in a process under manufacture.

The following describes the manufacturing method of the semiconductor device relating to the first embodiment of the present invention, with reference to FIG. 1 to FIG. 10.

According to the first embodiment as shown in FIG. 1 to FIG. 10 in order, a semiconductor device is manufactured using a p-type semiconductor substrate 011 in which an isolation insulator film 014 is formed. The description is given focusing on four regions (regions 101, 102, 103, and 104) divided by the isolation insulator film 014. In each of the four regions, a p-channel LDMOS transistor, an n-channel LDMOS transistor, a p-channel MOS transistor, and an n-channel MOS transistor are formed simultaneously. The details of the processes are described later.

The manufacturing method relating to the first embodiment is composed of the following processes:

process (a) of forming n-type well diffusion layer;

process (b) of forming p-type well diffusion layer;

process (c) of forming gate insulator film, gate conductive film, and resist film;

process (d) of forming first opening;

process (e) of forming p-type body layer;

process (f) of re-forming resist film;

process (g) of forming second opening;

process (h) of forming n-type body layer;

process (i) of forming gate electrode;

process (j) doping n-type impurity ions; and

process (k) doping p-type impurity ions.

2. Details

The following describes the processes in detail.

<Process (a) of Forming n-type Well Diffusion Layer>

In the process (a), n-type impurity ions are selectively doped into the regions 101 and 103 of the semiconductor substrate 011 to form n-type well diffusion layers 012 and 013, as shown in FIG. 1. Although not shown in the figure, the regions 102 and 104 are of course masked here.

<Process (b) of Forming p-type Well Diffusion Layer>

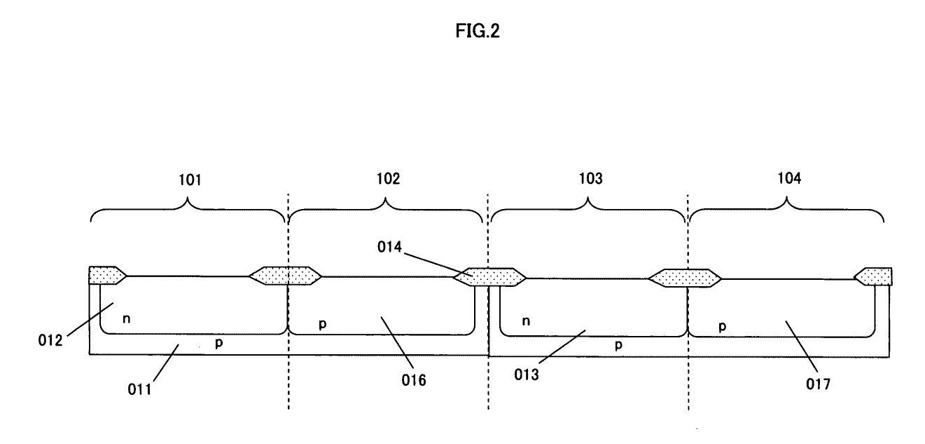

In the process (b), p-type impurity ions are selectively doped into the regions 102 and 104 of the semiconductor substrate 011 to form p-type well diffusion layers 016 and 017, as shown in FIG. 2. The regions 101 and 103 are of course masked here, too.

Here, although the semiconductor substrate 011 and the p-type well diffusion layers 016 and 017 have the same conductivity type, a concentration of the impurity ions included in each of the p-type well diffusion layers 016 and 017 is higher than a concentration of impurities included in the semiconductor substrate 011. Similarly in the figures subsequent to FIG. 2, when adjoining regions have the same conductivity type, the adjoining regions have different impurity concentrations.

<Process (c) of Forming Gate Insulator Film, Gate Conductive Film, and Resist Film>

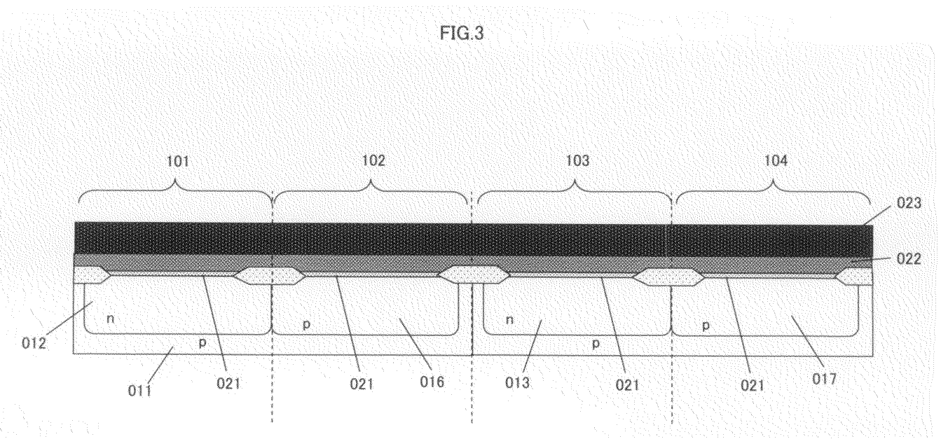

In the process (c), firstly, the semiconductor substrate 011 is cleaned to remove a natural oxide film, and then is annealed at 800[° C.] to 850[° C.] to form a gate insulator film 021 on a surface thereof (FIG. 3).

Next, a gate electrode material is laminated on the semiconductor substrate 011 to form a gate conductive film 022. As an example, the gate insulator film 021 has a film thickness of approximately 5 [nm] to 20 [nm], and the gate conductive film 022 has a film thickness of approximately 200 [nm] to 500 [nm].

Next, a photoresist is coated on the gate conductive film 022, and then the gate conductive film 022 is pre-baked to form a photoresist film 023.

<Process (d) of Forming First Opening>

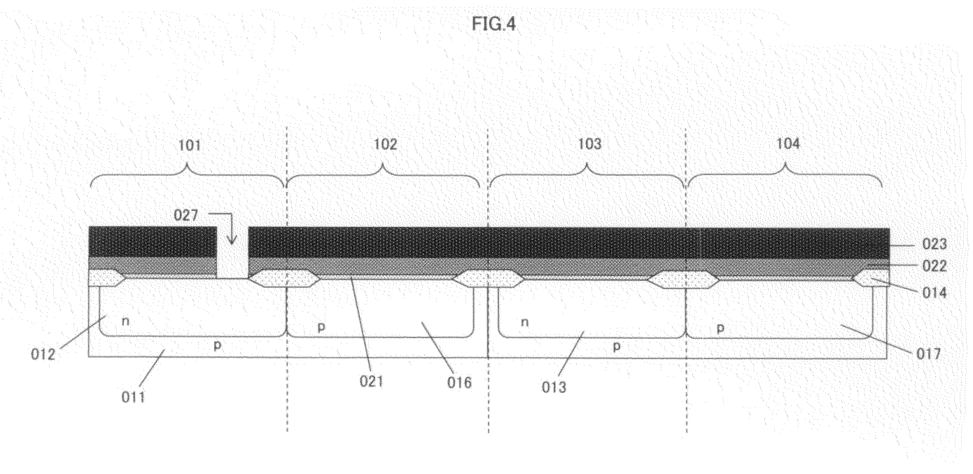

In the process (d), photolithography is performed using a photomask to remove a part of the photoresist film 023 formed in the region 101. Then, exposed parts of the gate conductive film 022 and the gate insulator film 021 formed in the region are etched to form a first opening 027 as shown in FIG. 4. The first opening 027 has a width of approximately 2 [μm], for example.

Here, photolithography and etching are realizable using general techniques, and accordingly detail descriptions thereof are omitted here.

<Process (e) of Forming p-type Body Layer>

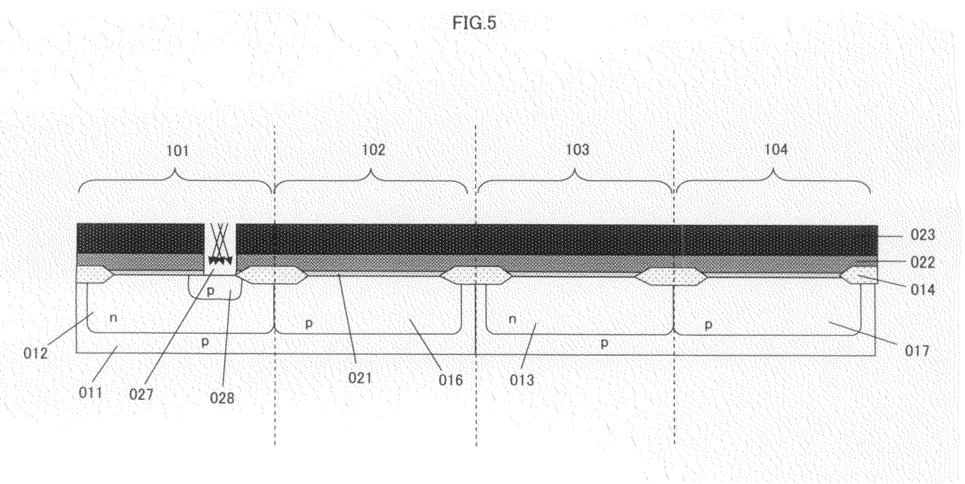

In the process (e), the p-type impurity ions are doped on a main surface of the semiconductor substrate 011 to form a p-type body layer 028 as shown in FIG. 5. Conditions for performing the doping include a dose amount of approximately 5E12 [cm⁻²] to 5E13 [cm⁻²] and incidence at an acceleration energy of approximately 50 [keV] to 150 [keV], for example. At this time, as shown in FIG. 5, the p-type impurity ions are doped while changing an incidence angle of the p-type impurity ions within a range of 20[°] to 45[°] with respect to a normal line of the semiconductor substrate 011. Note that the values of the incidence angle and the acceleration energy are just examples, and are determined depending on the shape of a p-type body layer to be formed or the concentration of the impurity ions.

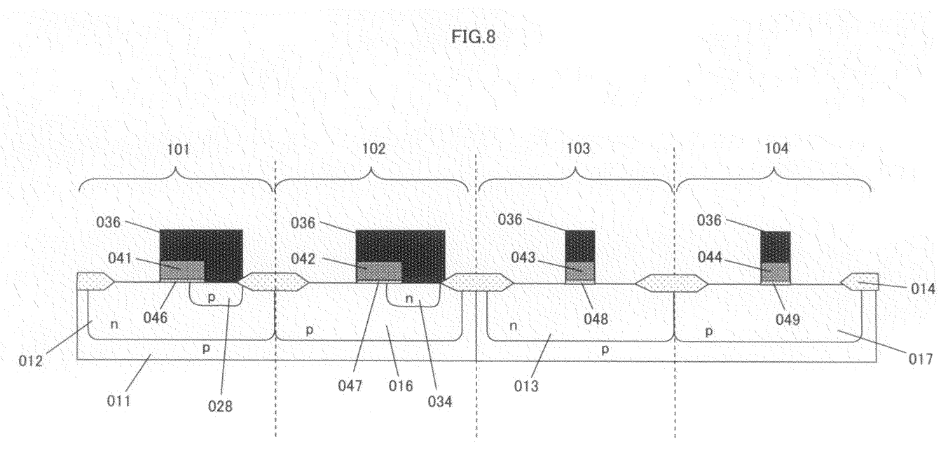

When the doping is performed under such conditions, remaining parts of the photoresist film 023, the gate conductive film 022, and the gate insulator film 021 function as a mask. The p-type semiconductor ions doped into the first opening 027 are diffused to the n-type well diffusion layer 012 to form a p-type body layer 028. Here, a part of an inner wall surface of the gate conductive film 022 facing the first opening 027 formed in the gate conductive film 022 constitutes one of lateral surfaces of a gate electrode 041 (FIG. 8), which is to be formed later.

<Process (f) of Re-forming Resist Film>

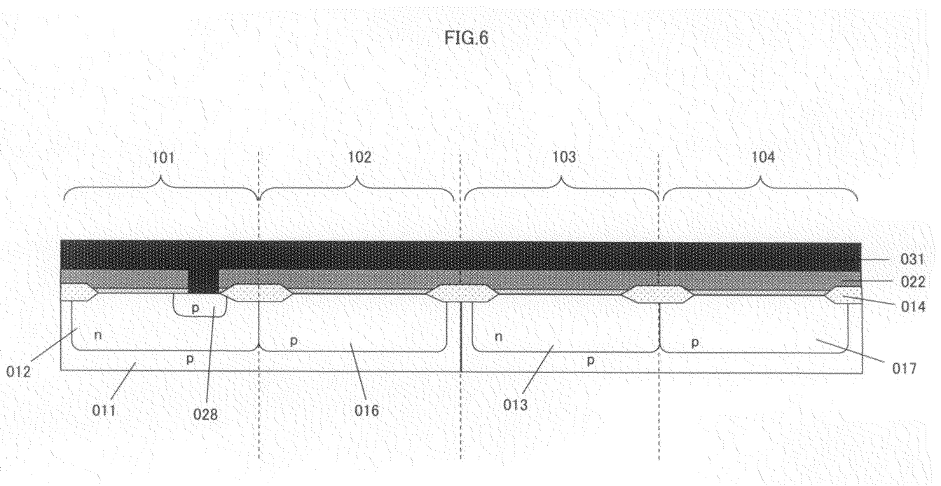

In the process (f), firstly, the photoresist film 023 remaining on the semiconductor substrate 011 is removed. Then, a new photoresist film 031 is formed as shown in FIG. 6.

<Process (g) of Forming Second Opening>

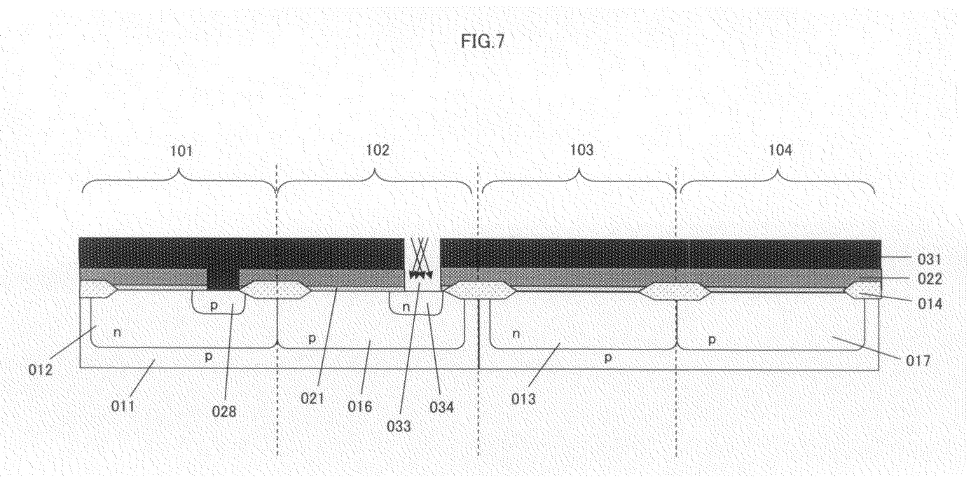

In the process (g), photolithography is performed in a procedure similar to that in the process (d) to remove part of the photoresist film 031 formed in the region 102 and etch an exposed part of the gate conductive film 022 and the gate insulator film 021 that are formed in the region 102. As a result, a second opening 033 as shown in FIG. 7 (an opening having a depth of approximately 2 [μm], for example) is formed.

<Process (h) of Forming n-type Body Layer>

In the process (h), n-type impurity ions are doped under conditions similar to those in the process (e) to form an n-type body layer 034 in the region 102 as shown in FIG. 7. In this case, again, a part of an inner wall surface of the gate conductive film 022 facing the second opening 033 constitutes one of lateral surfaces of a gate electrode 042 (see FIG. 8), which is to be formed later.

<Process (i) of Forming Gate Electrode>

In the process (i), firstly, a photoresist film 036 is re-generated in the similar way to that in the process (f), and photolithography is performed to remove a part of the photoresist film 036. Next, as shown in FIG. 8, an exposed part of the gate conductive film 022 and the gate insulator film 021 is etched. The gate electrode 041 and a gate insulator film 046, a gate electrode 042 and a gate insulator film 047, a gate electrode 043 and a gate insulator film 048, and a gate electrode 044 and a gate insulator film 049 are formed in the regions 101, 102, 103, and 104, respectively. Next, all parts of the photoresist film 036 remaining on the semiconductor substrate 011 are removed.

<Process (j) of Doping n-type Impurity Ions>

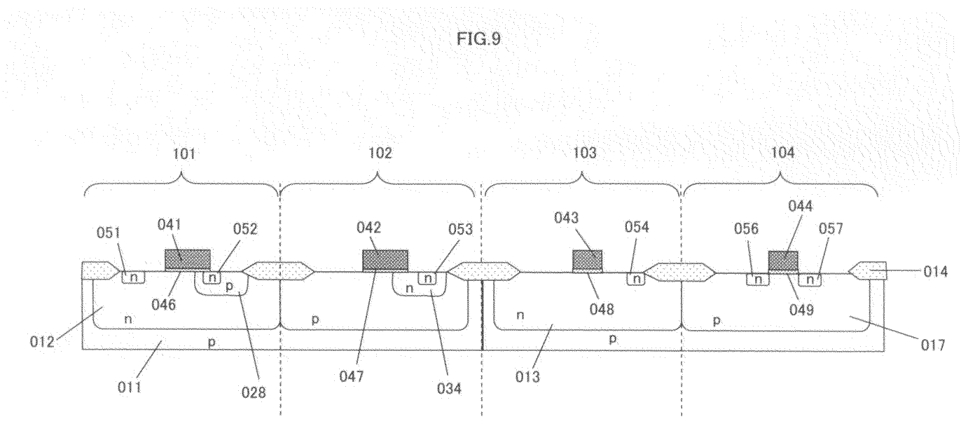

In the process (j), as shown in FIG. 9, n-type impurity ions are doped into predetermined positions of the semiconductor substrate 011 to form a drain diffusion layer 051 and a source diffusion layer 052 in the n-type well diffusion layer 012 and the p-type body layer 028 of the region 101, respectively, and form a body contact layer 053 in the n-type body layer 034 of the region 102. At the same time, a body contact layer 054 is formed in the n-type well diffusion layer 013 of the region 103, and a drain diffusion layer 056 and a source diffusion layer 057 are formed in the p-type well diffusion layer 017 of the region 104.

<Process (k) of Doping p-type Impurity Ions>

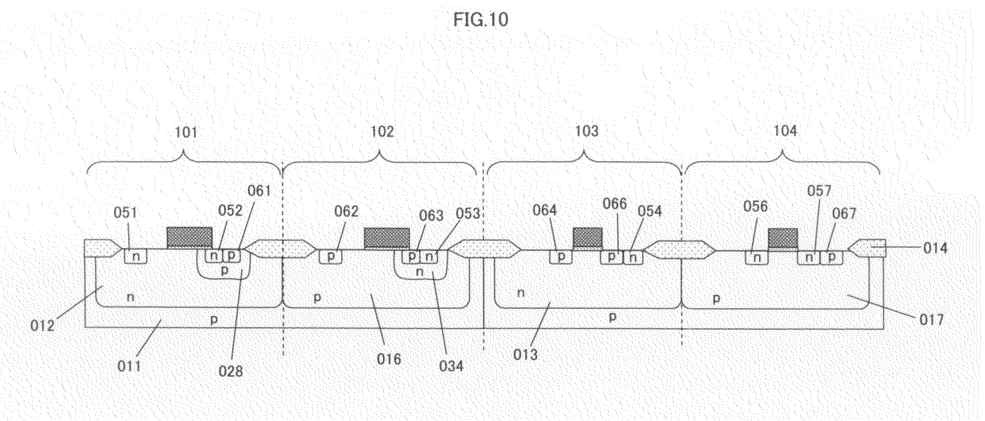

In the process (k), as shown in FIG. 10, n-type impurity ions are doped into predetermined positions of the semiconductor substrate 011 to form a body contact layer 061 in the p-type body layer 028 of the region 101, a drain diffusion layer 062 in the p-type well diffusion layer 016 of the region 102, and a source diffusion layer 063 in the n-type body layer 034 of the region 102.

At the same time, a drain diffusion layer 064 and a source diffusion layer 066 are formed in the n-type well diffusion layer 013 of the region 103, and a body contact layer 067 is formed in the p-type well diffusion layer 017 of the region 104.

Note that the processes (j) and (k) are realizable using conventional general arts, and accordingly detail descriptions thereof are omitted here.

3. Conclusion

By performing the processes (a) to (k) as described above, a p-channel LDMOS transistor, an n-channel LDMOS transistor, a p-channel MOS transistor, and an n-channel MOS transistor are formed in the regions 101 to 104 of the semiconductor substrate 011, respectively.

In the process (d) of forming the first opening 027, the photoresist film 023 is used as a mask for etching the gate conductive film 022 and the gate insulator film 021. Also, an inner wall surface of the gate conductive film 022 facing the first opening 027 constitutes an end surface of the gate electrode 041. In other words, in the process (e) of forming the p-type body layer 028, the gate electrode 041 functioning as a mask (in the first embodiment, a part of the gate conductive film 022 constituting the gate electrode 041 that includes an inner wall surface of the gate conductive film 022 facing the opening 027) completely conforms to the photoresist film 023. Accordingly, there does not exist a case where the doped impurity ions pass through the gate electrode 041 and reach the well diffusion layer. As a result, precise self-alignment is performed and uniform p-type body layers can be formed.

Also, there is no variation in positional relationship between the end surface of the photoresist film 023 and the end surface of the gate conductive film 022 (i.e. one of lateral surfaces of the gate electrode 041). As a result, it is possible to suppress variation with respect a range in which the p-type body layer 028 and the gate electrode 041 overlap each other when viewed in the cross sectional direction. In other words, it is possible to suppress variation with respect to an overlap range of the gate electrode 041 and the p-type body layer 028, that is, it is possible to suppress variation in channel length of the n-channel LDMOS transistors for each transistor.

The similar effect can be exhibited with respect to the channel length of the p-channel LDMOS transistor formed in the processes (g) and (h).

Therefore, the manufacturing method relating to the first embodiment can exhibit an effect that it is possible to realize the precise self-alignment, suppress the variation in channel length for each LDMOS transistor, and manufacture semiconductor devices having a stable performance.

The following describes an example using specific numerical values. In order to have a low threshold voltage of 1 [V] or less, the n-channel LDMOS transistor and the p-channel LDMOS transistor each need to have a channel length of 0.5 [μm] or less. The manufacturing method described in the first embodiment can extremely reduce the manufacturing variation even in the case of semiconductor devices having such a short channel length. Accordingly, it is possible to stably manufacture semiconductor devices having a short channel length of approximately 0.2 [μm] to 0.3 [μm].

Also, in the processes (e) and (h) of doping impurity ions, the impurity ions are doped at an incidence angle within a predetermined range from a normal line direction of the surface of the semiconductor substrate (at 20[°] to 45[°] from the normal line direction, for example). As a result, the impurity ions are diffused in a width larger than a width of an opening surface of the first opening 027. Therefore, according to the manufacturing method relating to the first embodiment, it is necessary to perform heat treatment processing at a comparatively low temperature, such as recovery of crystal damage by doping impurity ions (at approximately 850[° C.]) and prebaking of photoresist (at approximately 300[° C.]). However, it is unnecessary to perform heat treatment processing at a high temperature (1000[° C.] or higher) for diffusing the p-type body layer 028 and the n-type body layer 034 in the lateral direction. Accordingly, there is less influence on the characteristics of the MOS transistor formed in the same semiconductor substrate 011. Also, an excellent effect is exhibited that it is possible to simultaneously form LDMOS transistors and MOS transistors.

Furthermore, in the process (a), the n-type well diffusion layers (012 and 013) respectively for the n-channel LDMOS transistor and the p-channel MOS transistor are simultaneously formed using a single mask.

Similarly, in the processes (b), (i), (j), and (k), processing of forming the LDMOS transistor and processing of forming the MOS transistor are simultaneously performed using a single mask.

As a result, the manufacturing method relating to the first embodiment exhibits an effect that it is possible to suppress the increase in the number of processes for forming a plurality of transistors in the same substrate.

In the above first embodiment, the description has been given with respect to the case where an n-channel LDMOS transistor, a p-channel LDMOS transistor, a p-channel MOS transistor, and a p-channel MOS transistor are formed in regions that are horizontally arranged (the regions 101 to 104) in a semiconductor substrate. However, each of these transistors may be formed in an arbitrary position.

### Second Embodiment

The following describes a semiconductor device relating to a second embodiment of the present invention, with reference to the drawings.

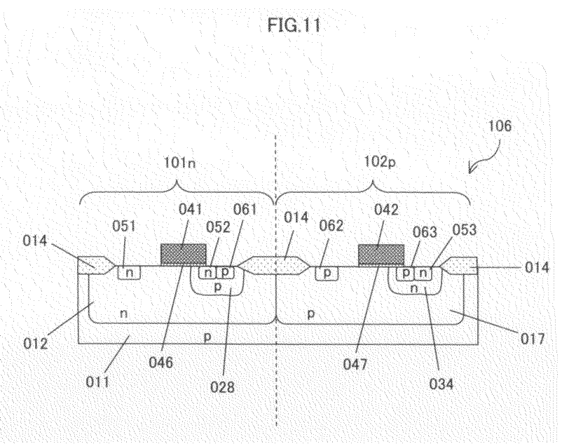

FIG. 11 is a sectional view showing the semiconductor device relating to the second embodiment. The semiconductor device includes a complementary LDMOS transistor 106, as shown in FIG. 11. The complementary LDMOS transistor 106 shown in

FIG. 11 is part of a semiconductor device manufactured by the manufacturing method relating to the first embodiment, which has referential numerals that are the same as those in the figures used for describing the first embodiment.

The complementary LDMOS transistor 106 is composed of an n-channel LDMOS transistor 101n and a p- channel LDMOS transistor 102p that are formed in the same semiconductor substrate 011. The n-channel LDMOS transistor 101n and the p-channel LDMOS transistor 102p are electrically disconnected with each other via an isolation insulator film 014.

The n-channel LDMOS transistor 101n is composed of an n-type well diffusion layer 012, a p-type body layer 028 and a drain diffusion layer 051 that are formed in the n-type well diffusion layer 012, a source diffusion layer 052 formed in the p-type body layer 028, a body contact layer 061, and a gate insulator film 046 and a gate electrode 041 that are formed on the n-type well diffusion layer 012.

The p-channel LDMOS transistor 102p is composed of a p-type well diffusion layer 017, an n-type body layer 034 and a drain diffusion layer 062 that are formed in the p-type well diffusion layer 017, a source diffusion layer 063 formed in the n-type body layer 034, a body contact layer 053, and a gate insulator film 047 and a gate electrode 041 that are formed on the n-type well diffusion layer 012.

As described in the first embodiment, the photoresist film 023 (FIG. 5) used as an etching mask for forming the gate electrode 041 is also used as a mask for forming the p-type body layer 028, without modification. This achieves high precision of the self -alignment, and extremely reduces variation in position of the p-type body layer 028 with respect to the gate electrode 041 for each transistor. Accordingly, variation in channel length of the n-channel LDMOS transistor 101n for each semiconductor device is extremely reduced. Similarly, variation in channel length of the p-channel LDMOS transistor 102p is extremely reduced.

As a result, even in the case of transistors having a short channel length, it is possible to extremely reduce an influence of the variation in channel length for each transistor on the threshold voltage.

As a specific example, in order to suppress a low threshold voltage of the transistor to 1 [V] or less, the transistor needs to have a channel length of 0.5 [μm] or less. Here, the complementary LDMOS transistor 106 relating to the second embodiment has a channel length of approximately 0.2 [μm] to 0.3 [μm]. Since the channel length is uniform within this range, it is possible to suppress the variation in channel length among semiconductor devices to approximately 5[%], at a low threshold voltage of approximately 0.8 [V].

Also, by doping p-type impurity ions having a high acceleration energy at an angle within a predetermined range (a range from 20[°] to 45[°] with respect to the normal line direction of the surface of the substrate, for example), a range of the p-type body layer 028, that is, a diffusion range of the p-type impurity ions is assured. This can improve the voltage resistance of the junction between the p-type body layer 028 and the n-type well diffusion layer 012. The similar effect can be exhibited with respect to a junction between the n-type body layer 034 and the p-type well diffusion layer 017 of the p-channel LDMOS transistor 102p. For example, it is possible to realize a complementary LDMOS transistor having a voltage resistance of approximately 15 [V] to 30 [V].

As described above, the complementary LDMOS transistor 106 relating to the second embodiment can operate at a low threshold voltage and a high voltage, and accordingly can be used for drivers for display devices, motor-driven drivers, and apparatuses such as power supply control ICs.

### Third Embodiment

The following describes a semiconductor device relating to a third embodiment of the present invention, with reference to the drawings.

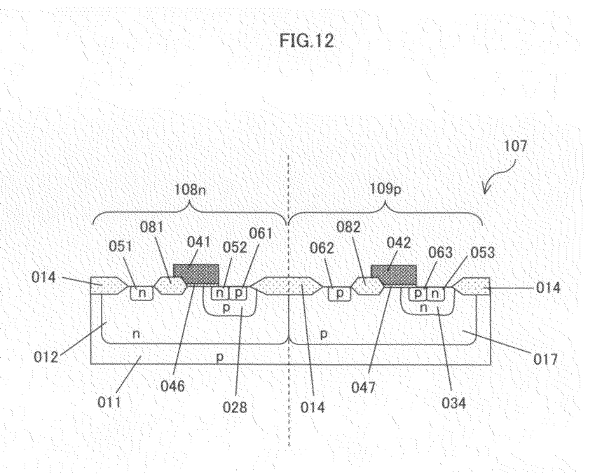

FIG. 12 is a sectional view showing a complementary LDMOS transistor 107 of the semiconductor device relating to the third embodiment.

As shown in FIG. 12, the complementary LDMOS transistor 107 has an insulator film between the gate electrode and the drain diffusion layer in the semiconductor device relating to the second embodiment. In FIG. 12, elements of the complementary LDMOS transistor 107 that are the same as those of the complementary LDMOS transistor 106 have the same numerical references.

The complementary LDMOS transistor 107 is composed of an n-channel LDMOS transistor 108n and a p-channel LDMOS transistor 109p.

The n-channel LDMOS transistor 108n has substantially the same structure as that of the n-channel LDMOS transistor 101n relating to the second embodiment. However, the n-channel LDMOS transistor 108n differs from the n-channel LDMOS transistor 101n in that the n-channel LDMOS transistor 108n includes an insulator film 081 provided between a gate electrode 041 and a drain diffusion layer 051. The insulator film 081 is, for example, an insulator film such as a LOCOS oxide film and an STI.

Also, the p-channel LDMOS transistor 109p has substantially the same structure as that of the p-channel LDMOS transistor 102p relating to the second embodiment. However, the p-channel LDMOS transistor 109p includes an insulator film 082 provided between a gate electrode 042 and a drain diffusion layer 062.

By including the insulator film 081 in this way, it is possible to suppress the concentration of electrical field in the side of the drain diffusion layer 051 of the gate electrode 041, and thereby improve the voltage resistance between the gate and the drain and the voltage resistance between the source and the drain.

As a specific example, the complementary LDMOS transistor 106 relating to the second embodiment has a voltage resistance of approximately 15 [V] to 30 [V]. Compared with this, the complementary LDMOS transistor 107 relating to the third embodiment can realize a high voltage of approximately 40 [V] to 100 [V].

### Fourth Embodiment

The following describes a semiconductor device relating to a fourth embodiment of the present invention, with reference to the drawings.

1. Outline

In the fourth embodiment, the following describes a manufacturing method of a semiconductor device including a complementary LDMOS transistor and a CMOS transistor that are formed in the same substrate, in the same way as in the first embodiment.

Differently from the first embodiment, the CMOS transistor is formed here so as to have a film thickness of a gate insulator film thereof thinner than that of a gate insulator film of the LDMOS transistor.

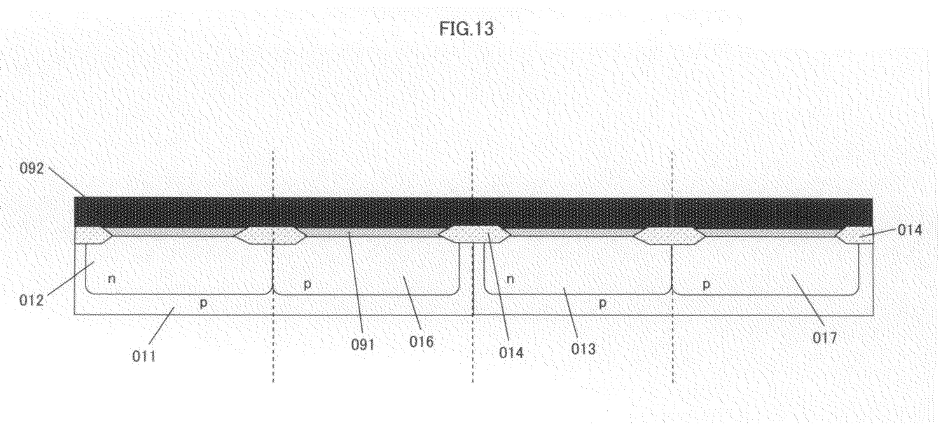

FIG. 13 to FIG. 16 are sectional views each showing a semiconductor device under manufacturing processes relating to the fourth embodiment. The following describes the manufacturing method relating to the fourth embodiment, with reference to FIG. 13 to FIG. 16. Note that the processes that are similar to those relating to the first embodiment are not described in detail. Also, the processes that are the same as those in the first embodiment are described with reference to the figures used in the first embodiment.

As shown in FIG. 1, also in the fourth embodiment, in four regions (regions 101, 102, 103, and 104) divided by the isolation insulator film 014, a p-channel LDMOS transistor, an n-channel LDMOS transistor, a p-channel MOS transistor, and an n-channel MOS transistor are formed simultaneously.

The manufacturing method relating to the fourth embodiment includes the following processes (a4) to (m4), and the processes (a4) to (b4) and the processes (f4) to (m4) are the same as the processes (a) to (b) and processes (d) to (k), respectively:

process (a4) of forming n-type well diffusion layer (similar to process (a));

process (b4) of forming p-type well diffusion layer (similar to process (b));

process (c4) of forming gate insulator film;

process (d4) of forming thin gate insulator film;

process (e4) of forming gate conductive film and resist film;

process (f4) of forming first opening (similar to process (d));

process (g4) of forming p-type body layer (similar to process (e));

process (h4) of re-forming resist film (similar to process (f));

process (i4) of forming second opening (similar to process (g));

process (j4) of forming n-type body layer (similar to process (h));

process (k4) of forming gate electrode (similar to process (i));

process (l4) of doping n-type impurity ions (similar to process (j)); and

process (m4) of doping p-type impurity ions (similar to process (k)).

2. Details

The following describes the manufacturing processes of the manufacturing method relating to the fourth embodiment. The processes that are the same as those relating to the first embodiment are not described here, and the differences from the processes relating to the first embodiment are mainly described.

<Processes (a4) to (b4)>

Processes that are the same as the processes (a) and (b) relating to the first embodiment are performed on a p-type semiconductor substrate 011 to form p-type well diffusion layers (016 and 017) and n-type well diffusion layers (012 and 013) in the regions 101 to 104, respectively, as shown in FIG. 2.

<Process (c4) of Forming Gate Insulator Film>

Firstly, a surface of the substrate is cleaned in the similar way to that in the first embodiment, and a gate insulator film 091 is formed as shown in FIG. 13. In the fourth embodiment, the gate insulator film 091 is formed so as to have a film thickness of approximately 10 [nm] to 200 [nm], for example (in the first embodiment, film thickness of approximately 5 [nm] to 20 [nm]).

Next, as shown in FIG. 13, a photoresist film 092 is formed on the gate insulator film 091.

<Process (d4) of Forming Thin Gate Insulator Film>

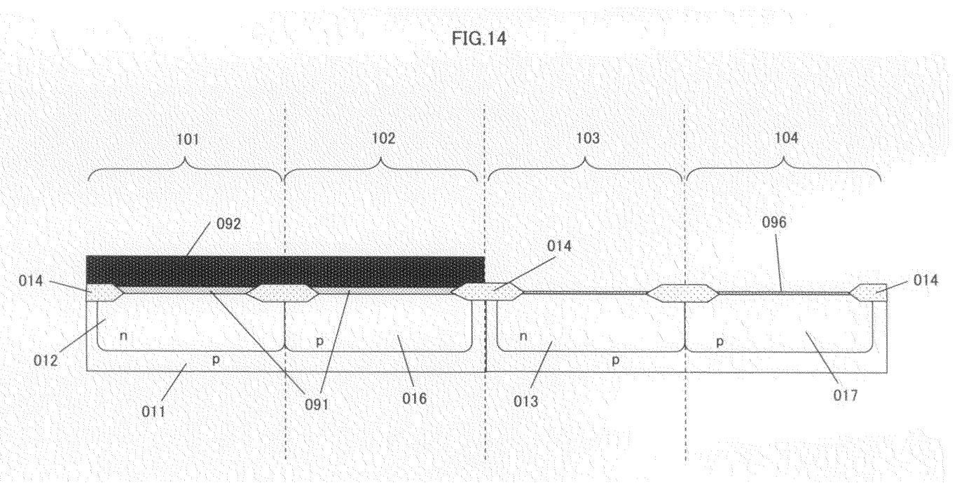

In the process (d4), photoresist is performed to remove a part of the photoresist film 092 that is formed in the regions 103 and 104, as shown in FIG. 14. Then, an exposed part of the gate insulator film 091 is etched.

Next, a gate insulator film is formed on a part of the semiconductor substrate 011 that falls within a range of the regions 103 and 104. Here, the gate insulator film is formed so as to have a film thickness thicker than that of the gate insulator film 091 formed in the process (c4). The gate insulator film has a film thickness of approximately 5 [nm] to 20 [nm], for example.

Hereinafter, the gate insulator film formed in the process (d4) is referred to as a “thin gate insulator film 096” so as to be distinguished from the gate insulator film 091.

<Process (e4) of Forming Gate Conductive Film and Resist Film>

In the process (e4), firstly, a remaining part of the photoresist film 092 on the semiconductor substrate 011 is removed.

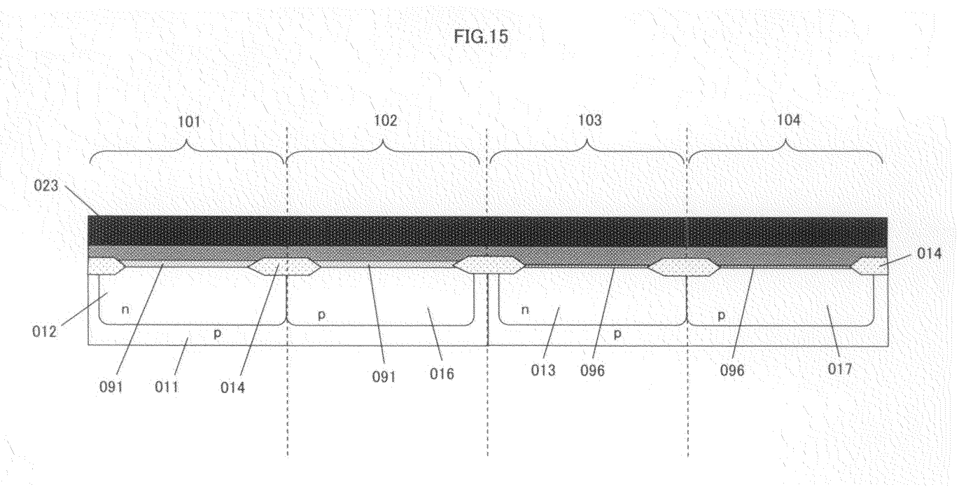

Next, as shown in FIG. 15, a gate conductive film 022 having a film thickness of approximately 200 [nm] to 500 [nm] is formed on the semiconductor substrate 011, and a photoresist film 023 is formed on the gate conductive film 022.

<Processes (f4) to (m4)>

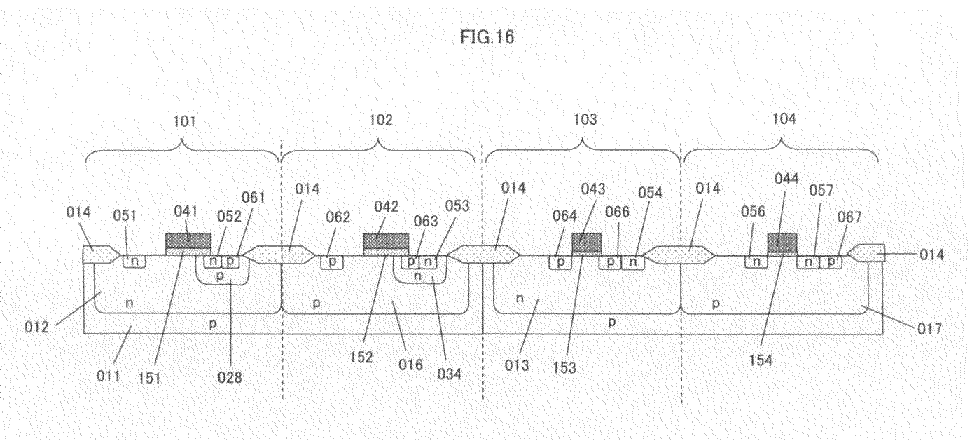

In the processes (f4) to (m4), processes of forming an opening, a body layer, a gate electrode, and the like are performed, in the similar way to the processes (d) to (k) relating to the first embodiment. As shown in FIG. 16, a complementary LDMOS transistor is formed in each of the regions 101 and 102 of the semiconductor substrate 011, and a CMOS transistor is formed in each of the regions 103 and 104 of the semiconductor substrate 011.

Here, a gate insulator film 151 of the n-channel LDMOS transistor formed in the region 101 and a gate insulator film 152 of the p-channel LDMOS transistor formed in the region 102 are each formed by removing part of the gate insulator film 091 shown in FIG. 15. A gate insulator film 153 of the p-channel MOS transistor formed in the region 103 and a gate insulator film 154 of the n-channel MOS transistor formed in the region 104 are each formed by removing part of the thin gate insulator film 096 shown in FIG. 15. As a result, the gate insulator films 151 and 152 of the complementary LDMOS transistor have film thickness thicker than those of the gate insulator films 153 and 154 of the CMOS transistor, respectively.

3. Conclusion

In the fourth embodiment, in the similar way to that in the first embodiment, without removing the photoresist film that has been used for forming the opening, that is, forming one of end surfaces of the gate electrode, the gate electrode and the photoresist film are used as a mask for forming the p-type body layer and the n-type body layer. As a result, the gate electrode completely conforms to the photoresist film. Also, by performing precise self-alignment, an excellent effect is exhibited that it is possible to form p-type and n-type body layers that constitute a body layer and suppress variation in channel length for each transistor.

Also, in the similar way to that in the first embodiment, when impurity ions are doped for forming a p-type body layer and an n-type body layer, the incidence angle is inclined from the normal line direction of the main surface of the semiconductor substrate. Accordingly, it is unnecessary to perform heat treatment processing at a high temperature (over 1000[° C.]) for diffusing the impurity ions in the lateral direction. This reduces an influence on the CMOS transistor.

Also, a common mask is used for forming complementary LDMOS transistors and CMOS transistors in many processes. This can suppress the increase in the number of processes.

In addition to these effects, according to the manufacturing method relating to the fourth embodiment, an excellent effect is exhibited that it is possible to simultaneously form CMOS transistors and complementary LDMOS transistors whose gate insulator films have a different film thickness only by slightly modifying the processes (processes (c4) to (e4)) based on the manufacturing method relating to the first embodiment. By forming a gate insulator film of a complementary LDMOS transistor so as to have a film thickness thicker than that of a gate insulator film of a CMOS transistor, a high voltage drive complementary LDMOS transistor having a gate voltage of approximately 10 [V] to 100 [V] is realized, for example. As described above, according to the semiconductor device manufactured by the manufacturing method relating to the fourth embodiment, it is possible to form a complementary LDMOS transistor having a high voltage and other element in the same semiconductor substrate. This can realize reduction in chip size of a driver or the like of apparatuses requested to have a high voltage such as display devices (for example, plasma TVs).

In the fourth embodiment, the description has been given with respect to the manufacturing method of the semiconductor device having the structure in which gate insulator films of two LDMOS transistors have film thickness thicker than those of two MOS transistors such that the two LDMOS transistors have a higher voltage resistance.

However, this is just one example. Any manufacturing method may be employed as far as film thicknesses of gate insulator films of LDMOS transistors and MOS transistors can be varied depending on purpose.

4. Modification Example of Fourth Embodiment

The following describes a modification example of the fourth embodiment.

This modification example differs from the fourth embodiment in the following point. According to this modification example, in the process (d4) of the manufacturing method relating to the fourth embodiment, a part of the gate insulator film 091 that is formed in a region where the drain diffusion layer of the complementary LDMOS transistor is intended to be formed is removed, and the thin gate insulator film 096 having a thin film thickness is formed in the region where the drain diffusion layer of the complementary LDMOS transistor is intended to be formed.

The following describes this modification example in detail with reference to the drawings.

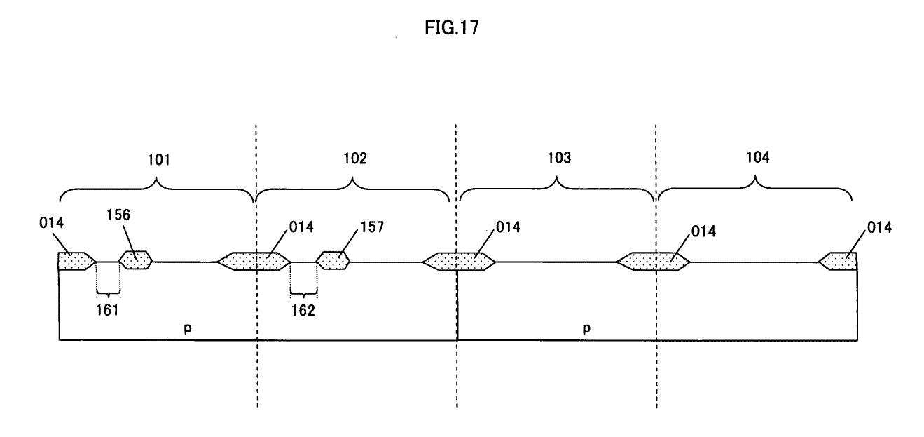

A semiconductor substrate 011 used here has formed therein isolation insulator films 014, as shown in FIG. 17. Among regions (regions 101 to 104) divided by the isolation insulator films 014, insulator films 156 and 157 are formed in the regions 101 and 102 in which LDMOS transistors are intended to be formed, respectively. The insulator film 156 is formed in a region located between a gate electrode and a drain diffusion layer of an n-channel LDMOS transistor. A region included in the region 101 closer to the drain that is surrounded by the isolation insulator film 014 and the insulator film 156 is referred to as an “n-drain formation intended region 161”. The insulator film 157 is formed in a position located between a gate electrode and a drain diffusion layer of a p-channel LDMOS transistor. A region included in the region 101 closer to the drain that is surrounded by the isolation insulator film 014 and the insulator film 157 is referred to as a “p-drain formation intended region 162”.

Firstly, the gate insulator film 091 and the photoresist film 092 are successively formed in the semiconductor substrate 011 (see FIG. 13) in the similar way to that in the processes (a4) to (c4) relating to the fourth embodiment.

<Process (d4′)>

Next, the photoresist film is removed in the similar way to that in the process (d4). Here, a part of the photoresist film that is formed in the n-drain formation intended region 161, the p-drain formation intended region 162, the regions 103 and 104 is removed.

Next, etching processing is performed using a remaining part of the photoresist film 092 as a mask to remove a part of the gate insulator film 091 that has not been masked. Next, in a region on the semiconductor substrate 011 that has not been masked by the photoresist film 092, that is, in the n-drain formation intended region 161, the p-drain formation intended region 162, and the regions 103 and 104, the thin gate insulator film 096 is formed. This completes the process (d4′).

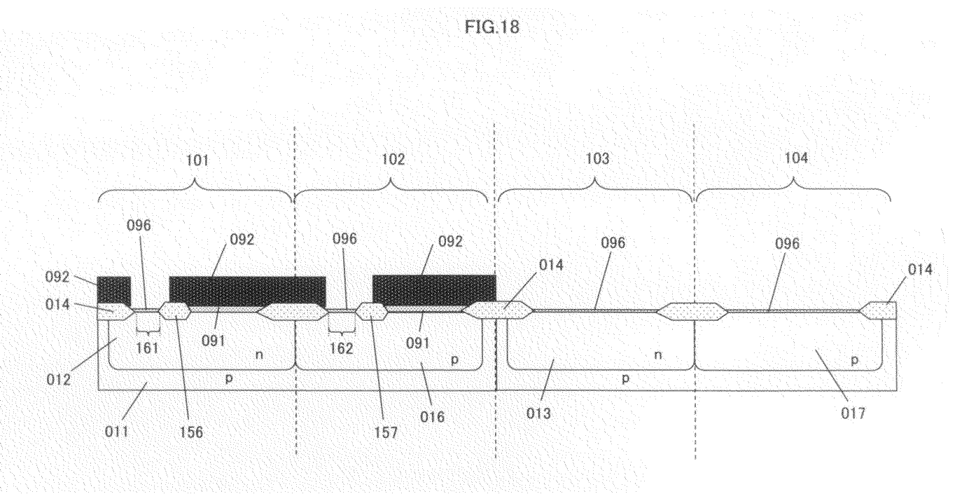

FIG. 18 is a sectional view showing the semiconductor device at the time of completion of the process (d4′).

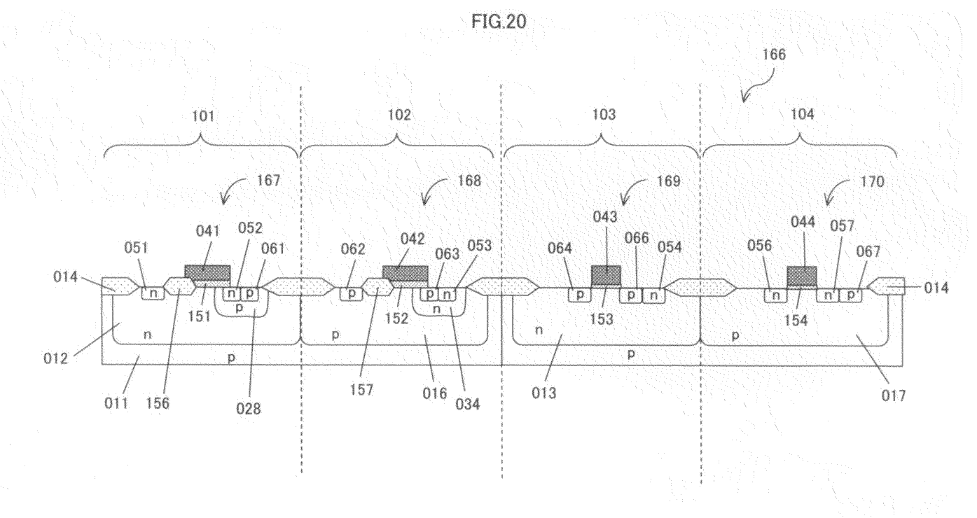

Then, by performing processes that are similar to the above processes (e4) to (m4), a p-type body layer 028 and an n-type body layer 034 are formed, and then a source diffusion layer and a drain diffusion layer are formed in each of the regions. As a result, a semiconductor device (see FIG. 20) is completed, which is substantially the same as the semiconductor device shown in FIG. 16.

Here, in the process (k4) of forming a gate electrode (similar to process (i)), the photoresist film 036 formed on the semiconductor substrate 011 is removed except a part thereof. Specifically, the photoresist film 036 is removed, except a part thereof that covers parts of the body layers (028 and 034) and the gate conductive film that are intended to be gate electrodes 041, 042, 043, and 044.

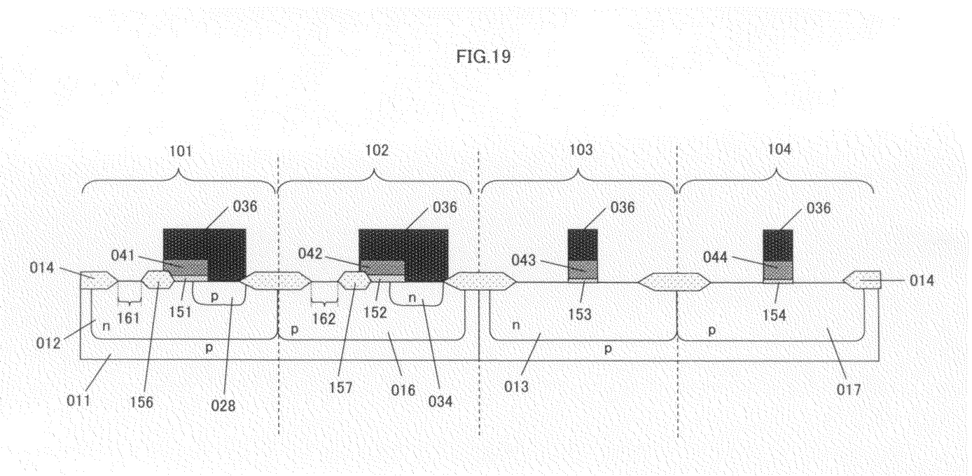

Next, an exposed part of the gate conductive film and the gate insulator film is etched. As a result of performing this process, the gate electrode and the gate insulator film are formed in each of the regions, as shown in FIG. 19.

By the way, a gate insulator film formed within a range that is not masked by the photoresist film 036 at this time is the thin gate insulator film 096 formed in the process (d4′). Accordingly, the film thickness of the gate insulator film is substantially uniform, and a time period necessary for performing etching is substantially uniform.

On the other hand, according to the manufacturing method relating to the fourth embodiment, the film thicknesses of the gate insulator films formed in the regions 101 and 102 are different from the film thicknesses of the gate insulator films formed in the regions 103 and 104. As a result, in the process (k4), a long time period is necessary for etching the gate insulator films formed in the regions 103 and 104. Also, the gate insulator films formed in the regions 103 and 104 are thin, and accordingly are excessively etched. This might cause the semiconductor substrate 011, well regions (013 and 017), and the isolation insulator film 014 to be trimmed.

However, according to this modification example, the gate insulator films respectively formed in the n-drain formation intended region 161, the p-drain formation intended region 162, and the regions 103 and 104 are each a thin gate insulator film. Accordingly, time periods respectively necessary for etching these gate insulators are substantially the same. This is unlikely to cause excessive etching of the gate insulators. In other words, an effect is exhibited that it is possible to suppress digging of the semiconductor substrate and reduction in film thickness of the isolation insulator films formed in the regions 103 and 104.

### Fifth Embodiment

The following describes a semiconductor device relating to a fifth embodiment of the present invention.

FIG. 20 is a sectional view showing a semiconductor device 166 relating to the fifth embodiment. The semiconductor device 166 shown in FIG. 20 includes a CMOS transistor and a complementary LDMOS transistor that are formed in the same substrate, and is manufactured by the manufacturing method relating to the modification example of the fourth embodiment described above.

As shown in FIG. 20, the semiconductor device 166 has the structure in which a complementary LDMOS transistor is provided in each of regions 101 and 102 of a semiconductor substrate 011, and a CMOS transistor is provided in each of regions 103 and 104 of the semiconductor substrate 011. The complementary LDMOS transistor is composed of an n-channel LDMOS transistor 167 formed in the region 101 and a p-channel LDMOS transistor 168 formed in the region 102. The CMOS transistor is composed of a p-channel MOS transistor 169 formed in the region 103 and an n-channel MOS transistor 170 formed in the region 104.

Gate insulator films 151 and 152 that constitute the complementary LDMOS transistor have film thickness thicker than those of gate insulator films 153 and 154 that constitute the CMOS transistor, respectively. For example, the gate insulator films 151 and 152 each have a film thickness of approximately 10 [nm] to 200 [nm]. Compared with these, the gate insulator films 153 and 154 each have a film thickness of approximately of 5 [nm] to 20 [nm].

As described in the modification example of the fourth embodiment, an unnecessary part of the gate insulator films formed in the n-drain formation intended region 161 and the p-drain formation intended region 162 (see FIG. 20) is etched at the same time when an unnecessary part of the gate insulator films formed in the regions 103 and 104 of the CMOS transistor is etched.

The gate insulator films formed in these regions have the substantially uniform film thickness, and accordingly excessive etching is unlikely to be performed. Therefore, the semiconductor device 166 has the structure in which less digging of the semiconductor substrate and less reduction in film thickness of the isolation insulator film.

As described above, the semiconductor device 166 relating to the fifth embodiment has less digging of the semiconductor substrate and less reduction in film thickness of the isolation insulator film. Accordingly, the semiconductor device 166 exhibits an excellent effect that it is possible to suppress occurrence of leakage current or hot carrier between the source and the drain of the CMOS transistor. Also, since the reduction in film thickness of the isolation insulator film is less, the semiconductor device 166 exhibits an excellent effect that it is possible to suppress the reduction in threshold voltage of the parasitic MOS transistor.

Furthermore, in the similar way to that in the semiconductor device relating to the second and third embodiments, since the n-type body layer and the p-type body layer of the LDMOS transistor are formed by performing precise self -alignment, there is an extremely small variation in channel length for each transistor. As a result, there is also a small variation in threshold voltage for each transistor while a threshold voltage is maintained low.

### Other Modification Examples

Although the present invention has been described based on the above embodiments, the present invention is of course not limited to the above embodiments. The present invention includes the following modification examples, for example.

(1) In the first and forth embodiments, the semiconductor device has the structure in which the n- channel LDMOS transistor, the p-channel LDMOS transistor, the p-channel MOS transistor, and the n-channel MOS transistor are formed simultaneously on the semiconductor substrate 011. However, the structure of the semiconductor device relating to the present invention is not limited to this. The semiconductor device relating to the present invention may have only to include at least one LDMOS transistor.

For example, in order to form a semiconductor device that includes a single LDMOS transistor, by using a photoresist film that has been used as a mask for etching a gate conductive film as a mask for forming a p-type or an n-type body layer, an effect is exhibited that it is possible to form a body layer in a precise position and as a result to manufacture a semiconductor device having small variations in channel length and threshold voltage for each transistor.

Also, in the above embodiments, the description has been provided of the manufacturing method of the semiconductor device that includes an LDMOS transistor and an MOS transistor. However, an element to be formed on the same substrate on which an LDMOS transistor is formed is not limited to an MOS transistor.

(2) In the description of the process (d) (of forming first opening) and the process (g) (forming second opening) in the above first embodiment, the gate conductive film and the gate insulator film are etched. However, the gate insulator film does not necessarily need to be etched. Similarly, in the fourth embodiment, the gate insulator film does not necessarily need to be etched for forming an opening.

(3) In the above embodiments and modification examples, when the body layer of the LDMOS transistor is formed, the impurity ions are doped while the incidence angle of the impurity ions is changed within the predetermined range in the normal line direction of the semiconductor substrate, and heat treatment processing for diffusing the body layer is not performed. However, this structure is not essential to the present invention.

Alternatively, the impurity ions may be doped at an angle in the normal line direction of the semiconductor substrate. Further alternatively, high heat treatment processing may be performed for diffusion. Even if heat treatment processing is performed, an end surface of the gate conductive film and an end surface of the photpresist film of the opening correspond to each other. This can exhibit an effect that it is possible to realize precise self -alignment.

(4) In the above embodiments and modification examples, when the body layer is formed, the impurity ions are doped while the incidence angle of the impurity ions is changed within the predetermined range in the normal line direction of the semiconductor substrate. As a result, it is considered that the impurity ions are included in the gate insulator film and around a part of the gate insulator film that is intended to be an end surface of a gate electrode.

In order to avoid the electrical influence caused by the impurity ions, one of the lateral surfaces of the gate electrode that is the wall surface of the opening may be thinly etched.

(5) In the modification example of the fourth embodiment, the description has been provided of the manufacturing method of the semiconductor device using the semiconductor substrate on which the insulator films 156 and 157 have been already formed. These insulator films are each an oxide insulator film (SiO₂) that has been formed prior to the above process (a4), using the LOCOS (Local Oxidation of Silicon) method or the STI method, for example.

The composition of the insulator films 156 and 157 is not limited to SiO₂, and the insulator films 156 and 157 may be formed using a method other than the LOCOS method and the STI method.

(6) The present invention may be any combination of the above embodiments and modifications.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be constructed as being included therein.

What is claimed is:

1. A manufacturing method of a semiconductor device including a first conductive LDMOS transistor that is composed of a first conductive drain diffusion layer and a second conductive body layer formed in a semiconductor substrate, a first conductive source diffusion layer and a body contact layer formed in the body layer, and a gate electrode formed on a region between the drain diffusion layer and the source diffusion layer, the manufacturing method comprising:
a process (a) of forming a first conductive well diffusion layer in the semiconductor substrate;
a process (b) of sequentially forming a gate insulator film, a gate conductive film, and a photoresist film on a region on the semiconductor substrate corresponding to the well diffusion layer;
a process (c) of performing photolithography to remove a part of the photoresist film formed in a predetermined region, and etching the gate conductive film using a remaining part of the photoresist film as a mask so as to form an opening in the predetermined region;
a process (d) of doping second conductive impurity ions using a remaining part of the gate conductive film and the remaining part of the photoresist film as a mask so as to form the body layer; and
a process (e) of removing the remaining part of the gate conductive film except a part corresponding to the gate electrode formed based on a part that constitutes a lateral surface of the gate conductive film facing the opening.

2. The manufacturing method of claim 1 wherein,
in the process (d), the second conductive impurity ions are doped while an incidence angle thereof is changed within a predetermined range.

3. The manufacturing method of claim 2 wherein,
in the process (d), the impurity ions are doped such that the LDMOS transistor has a channel length within a range from 0.1 μm to 0.4 μm.

4. The manufacturing method of claim 1, further comprising
a process of forming an insulator film in a position between the drain diffusion layer and the gate electrode.

5. A manufacturing method of a semiconductor device including a complementary MOS transistor and a complementary LDMOS transistor that are formed in a same semiconductor substrate, the manufacturing method comprising:
a process (a) of, in a semiconductor substrate in which a plurality of isolation insulator films are formed, forming a first well diffusion layer having a first conductivity type in a first region defined by one of the isolation insulator films, and forming a second well diffusion layer having the first conductivity type in a second region that is different from the first region;
a process (b) of forming a third well diffusion layer having a second conductivity type and a fourth well diffusion layer having the second conductivity type respectively in a third region and a fourth region in the semiconductor substrate that are each different from the first and second regions;
a process (c) of sequentially forming a gate insulator film, a gate conductive film, and a photoresist film on a part on the semiconductor substrate corresponding to the first to fourth regions;
a process (d) of performing photolithography to remove a part of the photoresist film that is formed in a predetermined range of the first region, and etching the gate conductive film using a remaining part of the photoresist film as a mask so as to form a first opening;
a process (e) of doping second conductive impurity ions using a remaining part of the gate conductive film and the remaining part of the photoresist film so as to form a first body layer;
a process (f) of removing the remaining part of the photoresist film, and forming a new photoresist film on the part corresponding to the first to fourth regions;
a process (g) of performing photolithography to remove a part of the new photoresist film that is formed in a predetermined range of the second region, and etching the remaining part of the gate conductive film using a remaining part of the new photoresist film as a mask so as to form a second opening;
a process (h) of doping first conductive impurity ions using a part of the gate conductive film remaining after being etched and the remaining part of the new photoresist film as a mask so as to form a second body layer having the first conductivity type;
a process (i) of removing the gate conductive film except a part of the first region corresponding to the gate electrode formed based on a part that constitutes a lateral surface of the gate conductive film facing the first opening, a part of the third region corresponding to the gate electrode formed based on a part that constitutes a lateral surface of the gate conductive film facing the second opening, and parts of the second and fourths regions corresponding to the gate electrode;
a process (j) of forming a first-conductive drain diffusion layer in the first well diffusion layer, forming a first-conductive source diffusion layer in the first body layer, forming a first-conductive body contact layer in the second well diffusion layer, forming a first-conductive body contact layer in the third body layer, and forming a first-conductive source diffusion layer and a first-conductive drain diffusion layer in the fourth well diffusion layer; and
a process (k) of forming a second-conductive body contact layer on the first body layer, forming a second-conductive source diffusion layer and a second-conductive drain diffusion layer in the second well diffusion layer, forming a second-conductive drain diffusion layer on the third well diffusion layer, forming a second-conductive source diffusion layer in the third body layer, and forming a second-conductive body contact layer in the fourth well diffusion layer.

6. The manufacturing method of claim 5 wherein,
in the process (c), the gate insulator films are formed in the first and third regions so as to have film thicknesses thicker than film thicknesses of the gate insulator films formed in the second and fourth regions.

7. The manufacturing method of claim 5 wherein,
the semiconductor device comprising:
a first-conductive LDMOS transistor formed in the first region;
a second-conductive MOS transistor formed in the second region;
a second-conductive LDMOS transistor formed in the third region; and
a first-conductive MOS transistor formed in the fourth region, and
in the process (c), the gate insulator is formed in a range of the first and third regions in which the gate electrode and the body layer having the first or second conductivity are to be formed so as to have a film thickness thinner than a film thickness of the gate insulator formed in other region.

8. A semiconductor device including at least one LDMOS transistor and being manufactured by performing:
a process (a) of forming a first conductive well diffusion layer in the semiconductor substrate;
a process (b) of sequentially forming a gate insulator film, a gate conductive film, and a photoresist film on a region on the semiconductor substrate corresponding to the well diffusion layer;
a process (c) of performing photolithography to remove a part of the photoresist film formed in a predetermined region, and etching the gate conductive film using a remaining part of the photoresist film as a mask so as to form an opening in the predetermined region;
a process (d) of doping second conductive impurity ions using a remaining part of the gate conductive film and the remaining part of the photoresist film as a mask so as to form the body layer; and
a process (e) of removing the remaining part of the gate conductive film except a part corresponding to the gate electrode formed based on a part that constitutes a lateral surface of the gate conductive film facing the opening.

9. A semiconductor device including a complementary MOS transistor and a complementary LDMOS transistor that are formed in a same semiconductor substrate and being manufactured by performing:
a process (a) of, in a semiconductor substrate in which a plurality of isolation insulator films are formed, forming a first well diffusion layer having a first conductivity type in a first region defined by one of the isolation insulator films, and forming a second well diffusion layer having the first conductivity type in a second region that is different from the first region;
a process (h) of forming a third well diffusion layer having a second conductivity type and a fourth well diffusion layer having the second conductivity type respectively in a third region and a fourth region in the semiconductor substrate that are each different from the first and second regions;
a process (c) of sequentially forming a gate insulator film, a gate conductive film, and a photoresist film on a part on the semiconductor substrate corresponding to the first to fourth regions;
a process (d) of performing photolithography to remove a part of the photoresist film that is formed in a predetermined range of the first region, and etching the gate conductive film using a remaining part of the photoresist film as a mask so as to form a first opening;
a process (e) of doping second conductive impurity ions using a remaining part of the gate conductive film and the remaining part of the photoresist film so as to form a first body layer;
a process (f) of removing the remaining part of the photoresist film, and forming a new photoresist film on the part corresponding to the first to fourth regions;
a process (g) of performing photolithography to remove a part of the new photoresist film that is formed in a predetermined range of the second region, and etching the remaining part of the gate conductive film using a remaining part of the new photoresist film as a mask so as to form a second opening;
a process (h) of doping first conductive impurity ions using a part of the gate conductive film remaining after being etched and the remaining part of the new photoresist film as a mask so as to form a second body layer having the first conductivity type;
a process (i) of removing the gate conductive film except a part of the first region corresponding to the gate electrode formed based on a part that constitutes a lateral surface of the gate conductive film facing the first opening, a part of the third region corresponding to the gate electrode formed based on a part that constitutes a lateral surface of the gate conductive film facing the second opening, and parts of the second and fourths regions corresponding to the gate electrode;
a process (j) of forming a first-conductive drain diffusion layer in the first well diffusion layer, forming a first-conductive source diffusion layer in the first body layer, forming a first-conductive body contact layer in the second well diffusion layer, forming a first-conductive body contact layer in the third body layer, and forming a first-conductive source diffusion layer and a first-conductive drain diffusion layer in the fourth well diffusion layer; and
a process (k) of forming a second-conductive body contact layer on the first body layer, forming a second-conductive source diffusion layer and a second-conductive drain diffusion layer in the second well diffusion layer, forming a second-conductive drain diffusion layer on the third well diffusion layer, forming a second-conductive source diffusion layer in the third body layer, and forming a second-conductive body contact layer in the fourth well diffusion layer.

10. The semiconductor device of claim 9, wherein
The complementary LDMOS transistor includes a gate insulator film that differs in film thickness from a gate insulator film included in the complementary MOS transistor.
